(19) United States
(12) Patent Application Publication
(10) Pub. No.: US 2024/0429147 A1
(43) Pub. Date: Dec. 26, 2024

(54) SEMICONDUCTOR APPARATUS

(71) Applicant: FUJI ELECTRIC CO., LTD., Kawasaki-shi (JP)

(72) Inventors: Toshio DENTA, Matsumoto-city (JP); Nobuya KOIKE, Maebashi-city (JP); Takashi KATSUKI, Matsumoto-city (JP); Shinichi TEZUKA, Matsumoto-city (JP); Nobuharu KUSAKARI, Matsumoto-city (JP)

(73) Assignee: FUJI ELECTRIC CO., LTD., Kawasaki-shi (JP)

(21) Appl. No.: 18/647,167

(22) Filed: Apr. 26, 2024

(30) Foreign Application Priority Data
Jun. 23, 2023 (JP) 2023-103308

(51) Int. Cl. H01L 23/498; H01L 23/00; H01L 23/31; H01L 25/065

(52) U.S. Cl. CPC H01L 23/49822; H01L 23/3142; H01L 23/49838; H01L 24/08; H01L 24/48; H01L 25/0652; H01L 2224/08145; H01L 2224/08225; H01L 2224/48132; H01L 2224/48138; H01L 2924/13055; H01L 2924/13091; H01L 2924/1431; H01L 2924/183

(57) ABSTRACT

A semiconductor apparatus includes (i) semiconductor chips including a power semiconductor chip including a switch and a control semiconductor chip including a control circuit configured to control the switch, (ii) redistribution layers including a first redistribution layer that electrically connects a first semiconductor chip to a second semiconductor chip from among the semiconductor chips, (iii) a first sealing material that seals the semiconductor chips and the redistribution layers, (iv) an insulating substrate including a first conductor layer, a second conductor layer and an insulating layer between the first and second conductor layers, in which the insulating substrate is fixed to the first sealing material to be opposed to the semiconductor chips and the redistribution layers, and (v) a second sealing material that seals the insulating substrate and the first sealing material.

### CROSS REFERENCE TO RELATED APPLICATION

This application claims priority from Japanese Patent Application No. 2023-103308 filed on Jun. 23, 2023, the entire contents of which are incorporated herein by reference.

### BACKGROUND OF THE INVENTION

### Field of the Invention

The present disclosure relates to semiconductor apparatuses for power electronic devices.

### Description of Related Art

A semiconductor apparatus for power electronic devices generates large amount heat and is therefore required to have a large capacity to dissipate heat.

A semiconductor apparatus described in Japanese Patent Application Laid-Open No. 2022-181819 includes a semiconductor chip (a semiconductor element in Japanese Patent Application Laid-Open No. 2022-181819), a substrate that includes an insulating base material containing a resin and two metal materials provided on both sides of the insulating base material, and a sealing material that seals the semiconductor chip and the substrate. The sealing material is a mold resin molded by transfer molding. The metal materials of the substrate each have an exposed surface not covered by the sealing material. Thus, heat generated by the semiconductor chip is dissipated via the substrate in the semiconductor apparatus in Japanese Patent Application Laid-Open No. 2022-181819.

An external connection terminal and a pad of the semiconductor chip are connected to each other by bonding wire in the semiconductor apparatus in Japanese Patent Application Laid-Open No. 2022-181819. This configuration has a problem in that wire deformation can easily occur due to the mold when transfer molding of the sealing material is performed.

A semiconductor apparatus described in Japanese Patent Application Laid-Open No. 2022-152703 has substantially the same heat dissipation member as the substrate in Japanese Patent Application Laid-Open No. 2022-181819. In Japanese Patent Application Laid-Open No. 2022-152703, a main electrode of a semiconductor chip (a semiconductor element in Japanese Patent Application Laid-Open No. 2022-152703) is connected to a conductor pattern formed on a metal material of the heat dissipation member. Furthermore, a signal terminal of the semiconductor chip is connected to the conductor pattern on the metal material of the heat dissipation member via a redistribution layer, and the main electrode is connected to the conductor pattern. No bonding wire is used for connecting the semiconductor chip to an external connection terminal in Japanese Patent Application Laid-Open No. 2022-152703, and therefore the problem of wire deformation is avoided.

Reduction in size of semiconductor chips has been demanded in association with the demand for reduction in size of power electronic devices. However, reduction in size of semiconductor chips makes it difficult to use bonding wire to connect semiconductor chips as well as to connect a semiconductor chip with an external connection terminal. In the technique disclosed in Japanese Patent Application Laid-Open No. 2022-152703, the semiconductor chip is connected to the external connection terminal via the redistribution layer and the conductor pattern of the heat dissipation member. Japanese Patent Application Laid-Open No. 2022-152703 is silent about how semiconductor chips are connected to each other with wires for an IPM (Intelligent Power Module). If a redistribution layer is used as in the technique of Japanese Patent Application Laid-Open No. 2022-152703, wiring is arranged to connect one semiconductor chip, the redistribution layer, the conductor pattern of the heat dissipation member, the redistribution layer, and another semiconductor chip in this order. The wiring length of such a path is long, resulting in large wiring inductance.

This disclosure has been made in view of the circumstances described above, and an object of this disclosure is to provide techniques for wiring connection between semiconductor chips in a semiconductor apparatus without bonding wire.

### SUMMARY OF THE INVENTION

A semiconductor apparatus according to one aspect of the present disclosure includes (i) semiconductor chips including a power semiconductor chip including a switch and a control semiconductor chip including a control circuit configured to control the switch, (ii) redistribution layers including a first redistribution layer that electrically connects a first semiconductor chip to a second semiconductor chip from among the semiconductor chips; (iii) a first sealing material that seals the semiconductor chips and the redistribution layers; (iv) an insulating substrate including a first conductor layer, a second conductor layer, and an insulating layer between the first and second conductor layers, in which the insulating substrate is fixed to the first sealing material to be opposed to the semiconductor chips and the redistribution layers; and (v) a second sealing material that seals the insulating substrate and the first sealing material.

The redistribution layers may include a second redistribution layer configured to electrically connect the first semiconductor chip to an external connection terminal protruding to an outside of the second sealing material.

The external connection terminal may protrude from a side surface of the second sealing material to an outside.

The second distribution layer may have an exposed surface uncovered by the first sealing material, and the external connection terminal may be connected to the exposed surface.

A semiconductor apparatus according to another aspect of the present disclosure includes (i) semiconductor chips including a power semiconductor chip including a switch and a control semiconductor chip including a control circuit configured to control the switch, (ii) redistribution layers including a first redistribution layer that electrically connects a first semiconductor chip and a second semiconductor chip from among the semiconductor chips; (iii) a first sealing material that seals the semiconductor chips and the redistribution layers; (iv) a first insulating substrate; (v) a second insulating substrate; and (vi) a second sealing material.

Each of the first and second insulating substrates includes a first conductor layer, a second conductor layer, and an insulating layer between the first and second conductor layers. Each of the first and second insulating substrates is fixed to the first sealing material such that the semiconductor chips and the redistribution layers are located between the first and second insulating substrates.

The second sealing material seals the first insulating substrate, the first sealing material, and the second insulating substrate.

According to another aspect, the semiconductor apparatus further includes an external connection terminal protruding from a side surface of the second sealing material surrounding a region between the first and second insulating substrates to an outside of the second sealing material.

The redistribution layers include a third redistribution layer that electrically connects the first semiconductor chip from among the plurality of semiconductor chips to the external connection terminal via the second conductor layer of the first insulating substrate or the second insulating substrate.

According to this disclosure, wiring connection between semiconductor chips can be achieved without bonding wire in a semiconductor apparatus. Due to use of a first redistribution layer, the length of wiring electrically connecting semiconductor chips can be shortened, and the wiring inductance can be reduced.

### BRIEF DESCRIPTION OF THE DRAWINGS

FIG. 1 is a circuit diagram illustrating a configuration of an IPM as an example of an applicable target of this disclosure.

FIG. 2 is a plan view illustrating a configuration of a part of a semiconductor apparatus according to a first embodiment of this disclosure.

FIG. 3 is a cross-sectional view taken along a line IIa-IIb in FIG. 2.

FIG. 4 is a plan view illustrating a configuration of another part of the semiconductor apparatus.

FIG. 5 is a cross-sectional view taken along a line I2a-I2b in FIG. 4.

FIG. 6 is a cross-sectional view illustrating a configuration of a semiconductor apparatus according to a second embodiment of this disclosure.

FIG. 7 is a cross-sectional view illustrating a configuration of a semiconductor apparatus according to a third embodiment of this disclosure.

FIG. 8 is a perspective view illustrating the appearance of the semiconductor apparatus.

FIG. 9 is a cross-sectional view illustrating a configuration of a semiconductor apparatus according to another embodiment of this disclosure.

### DESCRIPTION OF THE EMBODIMENTS

Embodiments of the present disclosure are explained below with reference to the drawings.

### Applicable Targets

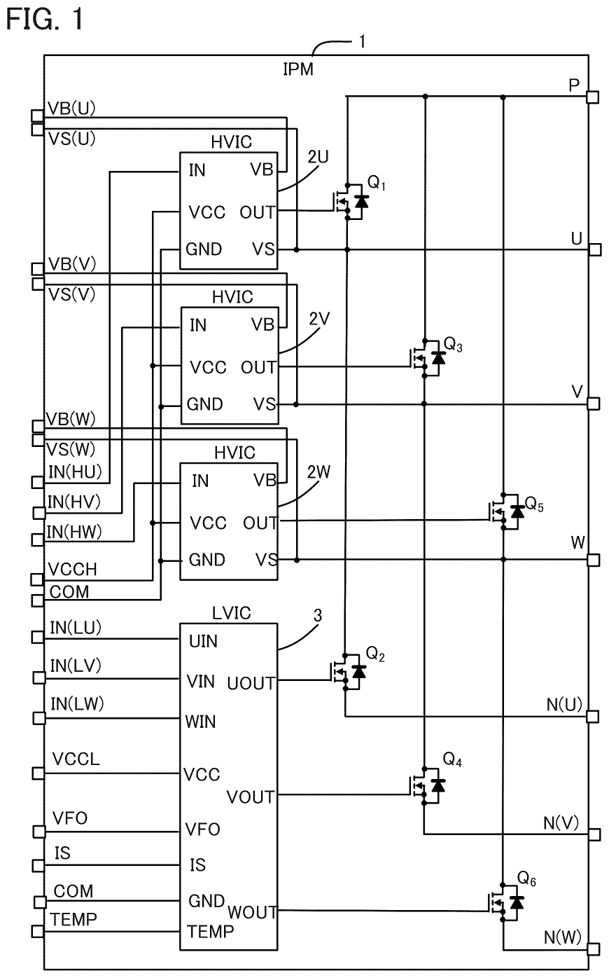

FIG. 1 is a circuit diagram illustrating a configuration of an IPM 1 as an applicable target of this disclosure. The IPM 1 includes switches and a control circuit, which configure a three-phase inverter. In FIG. 1, the positive side of a DC power supply (not shown) is connected to a terminal P. The negative side of the DC power supply is connected to terminals N(U), N(V), and N(W).

The IPM 1 includes switches (switching elements) Q₁ to Q₆. The switches Q₁ to Q₆ are wide band-gap semiconductor elements using SiC or the like. It is envisaged that the switches are SiC elements. Each of the switches Q₁ to Q₆ may be configured by a MOSFET (Metal Oxide Semiconductor Field Effect Transistor) and a parasitic diode.

The switches Q₁, Q₃, and Q₅ are U-phase, V-phase, and W-phase high-side switches, respectively, in each of which the drain is connected to the terminal P. The switches Q₂, Q₄, and Q₆ are U-phase, V-phase, and W-phase low-side switches with sources connected to the terminals N(U), N(V), and N(W), respectively.

The sources of the switches Q₁, Q₃, and Q₅ are connected to the drains of the switches Q₂, Q₄, and Q₆, respectively. A common connection point between the source of the switch Q₁ and the drain of the switch Q₂ is connected to a terminal U. A common connection point between the source of the switch Q₃ and the drain of the switch Q₄ is connected to a terminal V. A common connection point between the source of the switch Q₅ and the drain of the switch Q₆ is connected to a terminal W. Three-phase load is connected to the terminals U, V, and W.

The IPM 1 includes HVICs (High Voltage Integrated Circuits) 2U, 2V, and 2W, which are Si elements, and an LVIC (Low Voltage Integrated Circuit) 3. These circuits each have two functions, one of which is to control driving of a corresponding switch in the IPM 1, and the other of which is to protect the switch. In more detail, the HVICs 2U, 2V, and 2W control turning ON and OFF of the high-side switches Q₁, Q₃, and Q₅, respectively. The LVIC 3 controls turning ON and OFF of the low-side switches Q₂, Q₄, and Q₆ and protects elements in the IPM 1.

### First Embodiment

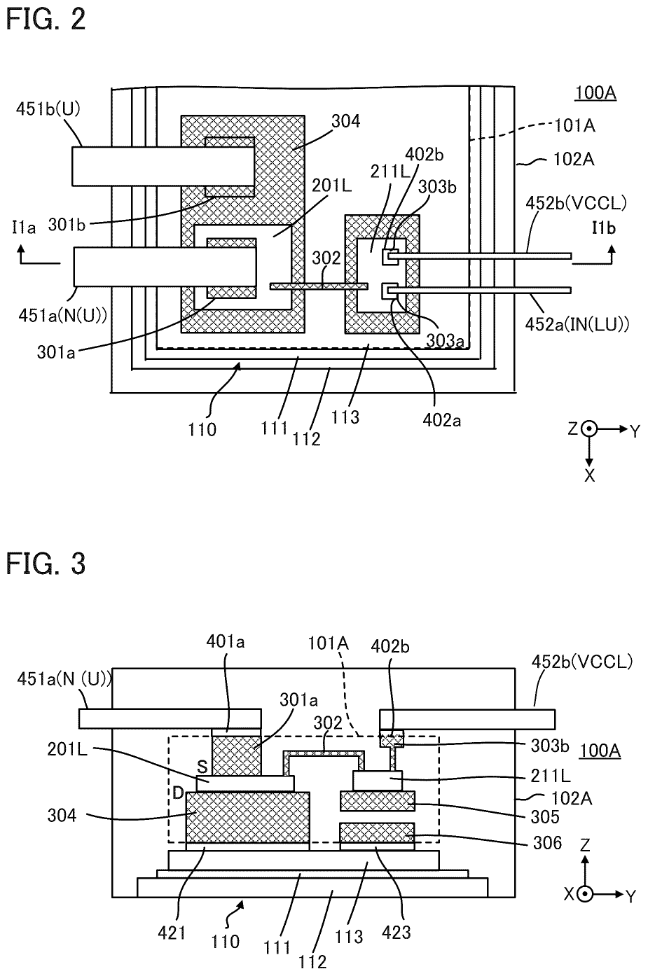

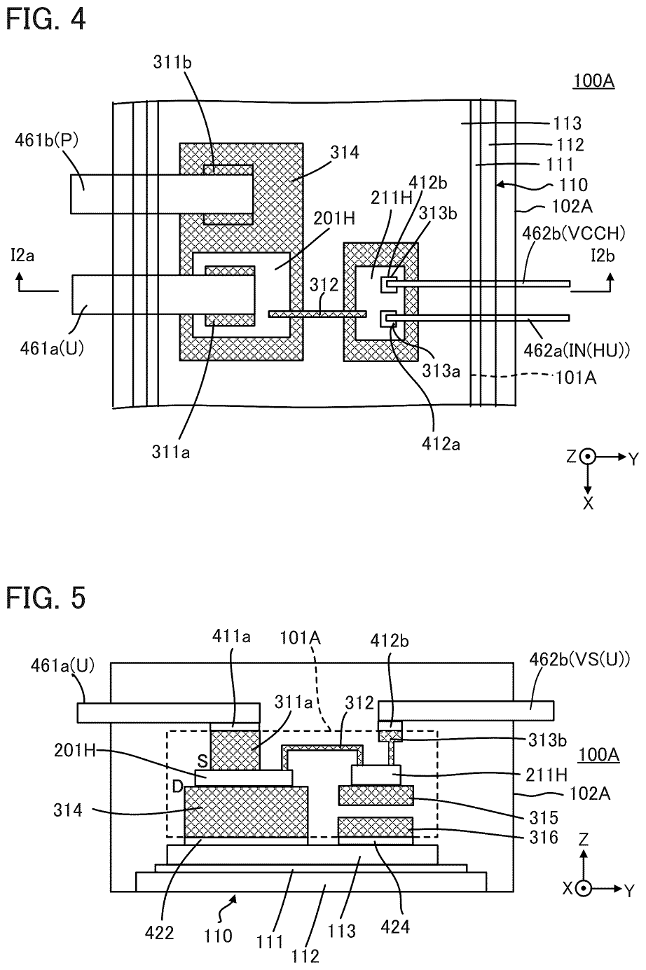

FIG. 2 is a plan view illustrating a configuration of a part of a semiconductor apparatus 100A according to a first embodiment of this disclosure. FIG. 3 is a cross-sectional view taken along a line I1a-I1b in FIG. 2. FIG. 4 is a plan view illustrating a configuration in a region away from the region illustrated in FIG. 2 in a −X direction (described later). FIG. 5 is a cross-sectional view taken along a line 12a-12b in FIG. 4.

In one example, the outer shape of the semiconductor apparatus 100A may be flat as a whole. In the configuration of the present embodiment below, it is envisaged that an orthogonal coordinate system includes an X-axis, a Y-axis and a Z-axis. The Z-axis is parallel to a plate thickness direction of the semiconductor apparatus 100A. The X-axis and the Y-axis are perpendicular to each other and perpendicular to the Z-axis. Hereinafter, a plane perpendicular to a Z-axis direction may be referred to as an “XY plane” for the convenience of description. For example, in FIGS. 3 and 5, the upward direction and the downward direction on the diagrams may be referred to as a “+Z side” and a “−Z side,” respectively. The relation between these directions and a vertical direction is not particularly limited to any specific one.

As illustrated in FIGS. 2 to 5, the semiconductor apparatus 100A includes a first sealing material 101A, an insulating substrate 110, and a second sealing material 102A. In the example of these drawings, the first sealing material 101A includes power semiconductor chips 201L and 201H, control semiconductor chips 211L and 211H, and redistribution layers 301a, 301b, 304, 314, 302, 312, 303a, 303b, 313a, 313b, 305, 306, 315, and 316.

In the present embodiment, switches of the power semiconductor chips 201L and 201H are vertical semiconductor elements in which a current flows in a thickness direction of a semiconductor substrate. A MOSFET comprising each of the control semiconductor chips 211L and 211H is a lateral semiconductor element in which a current flows in a surface direction of a semiconductor substrate (i.e., a direction parallel to an XY plane).

The insulating substrate 110 includes a first conductor layer 112, a second conductor layer 113, and an insulating layer 111 between the first conductor layer 112 and the second conductor layer 113. The first conductor layer 112 has no gaps throughout its entire area. The second conductor layer 113 has one or more conductor patterns formed therein. The second conductor layer 113 is fixed to the first sealing material 101A to be opposed to the semiconductor chips and the redistribution layers in the first sealing material 101A.

External connection terminals 451a, 451b, 461a, and 461b are provided above (on a +Z side plane of) the first sealing material 101A. The second sealing material 102A seals the insulating substrate 110, the first sealing material 101A, and the external connection terminals 451a, 451b, 461a, and 461b. For example, the first sealing material 101A and the second sealing material 102A are epoxy resin. The first conductor layer 112 of the insulating substrate 110 may be exposed from the insulating substrate 110 side surface of the second sealing material.

First, the first sealing material 101A including semiconductor chips and redistribution layers is formed in the first embodiment. Next, a redistribution layer uncovered by the first sealing material 101A and the insulating substrate 110 are bonded to each other by a conductive bonding member such as solder. Next, the external connection terminals 451a, 451b, 461a, and 461b are bonded to the redistribution layer uncovered by the first sealing material 101A. The first sealing material 101A with the external connection terminals bonded thereto and the insulating substrate 110 are then sealed by the second sealing material 102A.

Redistribution layers in the first sealing material 101A will be described. In the present embodiment, as illustrated in FIGS. 2 to 5, a first semiconductor chip among the semiconductor chips is electrically connected to a second semiconductor chip by a redistribution layer. Furthermore, the first semiconductor chip among the semiconductor chips is electrically connected to an external connection terminal by a redistribution layer in the present embodiment. The redistribution layer is a wiring layer formed by metal plating and an insulating layer. Specifically, the redistribution layer is formed by forming a pattern by photoresist and performing electrolytic plating. The type of metal for the redistribution layer may be selected considering electrical conductivity, thermal conductivity, the bonding property in a later process, and the cost. The type of redistribution layer May be selected from copper, tin, gold, nickel, and alloys of these metals and is preferably copper. A metal layer suitable for solder bonding may be formed on an outermost surface (the surface to be connected to the outside) of the redistribution layer. While the semiconductor apparatus 100A according to the present embodiment includes semiconductor chips other than the power semiconductor chips 201L and 201H and the control semiconductor chips 211L and 211H, illustrations of those semiconductor chips and redistribution layers associated therewith are omitted.

As illustrated in FIGS. 2 and 3, the power semiconductor chip 201L and the control semiconductor chip 211L are provided in the first sealing material 101A. Specifically, both are located in a region away from the insulating substrate 110 in a Z-direction and arranged in a Y-direction (the direction perpendicular to the thickness direction of the semiconductor apparatus 100A). For example, the power semiconductor chip 201L includes 15 the switch Q₂ in FIG. 1. The control semiconductor chip 211L is a control semiconductor chip corresponding to the LVIC 3 in FIG. 1.

The source and the gate of the MOSFET are formed on the top surface (the +Z side surface) of the power semiconductor chip 201L. The drain of the MOSFET is formed on the bottom surface (the −Z side surface) of the power semiconductor chip 201L. The redistribution layer 301a is located above (on the +Z side of) the power semiconductor chip 201L and connected to the source of the MOSFET. A connection pad 401a is provided on (on the +Z side of) the redistribution layer 301a. The redistribution layer 301a is connected to the external connection terminal 451a via the connection pad 401a. That is, the redistribution layer 301a has an exposed surface uncovered by the first sealing material 101A, and to this exposed surface, the external connection terminal 451a is connected via the connection pad 401a. For example, the connection pad 401a is a conductive bonding member, such as solder. The same applies to another connection pad. The external connection terminal 451a protrudes from the side surface of the second sealing material 102A to the outside of the second sealing material 102A and is, for example, the terminal N(U) in FIG. 1.

The redistribution layer 302 is provided above (on the +Z side of) the power semiconductor chip 201L and the control semiconductor chip 211L. The redistribution layer 302 extends in the Y-direction (perpendicular to the thickness direction of the semiconductor apparatus 100A). One end of the redistribution layer 302 is bent toward the insulating substrate 110 with respect to the external connection terminal 451a (452b) and connected to the gate of the MOSFET of the power semiconductor chip 201L. The other end of the redistribution layer 302 is bent toward the insulating substrate 110 with respect to the external connection terminal 451a and connected to a signal terminal of the control semiconductor chip 211L. For example, this signal terminal is a terminal UOUT of the LVIC 3 in FIG. 1. That is, the redistribution layer 302 is a first redistribution layer that electrically connects the first semiconductor chip (e.g., 201L) among the semiconductor chips to the second semiconductor chip (e.g., 211L).

The redistribution layer 305 is provided under (on the −Z side of) the control semiconductor chip 211L. The redistribution layer 306 is arranged below the redistribution layer 305. The second conductor layer 113 of the insulating substrate 110 has a conductor pattern formed therein. The redistribution layer 305 is connected to that conductor pattern via a bonding layer (not illustrated). For example, the control semiconductor chip 211L and the redistribution layer 305 are bonded to each other by a conductive bonding member (not illustrated), such as solder, Ag paste, sintered Ag material, and sintered Cu material. The redistribution layer 305 acts as a wiring path that supplies a GND potential to the back (the −Z side surface) of the control semiconductor chip 211L. The redistribution layer 306 is connected to another conductor pattern in the second conductor layer 113 via a bonding layer 423. The redistribution layer 306 does not serve as a wiring path. The redistribution layer 306 is a redistribution layer for stabilizing adhesion between the first sealing material 101A and the insulating substrate 110 and may be omitted. The bonding layer 423 is a conductive bonding member such as solder. The same applies to another bonding layer.

Two signal terminals are provided on the top surface (the +Z side surface) of the control semiconductor chip 211L. One signal terminal is, for example, a terminal UIN of the LVIC 3 in FIG. 1. The signal terminal is connected to the redistribution layer 303a above the control semiconductor chip 211L and connected to an external connection terminal 452a via a connection pad 402a. The other signal terminal is, for example, a terminal 20) VCC of the LVIC 3 in FIG. 1. The signal terminal is connected to the redistribution layer 303b above the control semiconductor chip 211L and connected to the external connection terminal 452b via a connection pad 402b. That is, the redistribution layer 303a has an exposed surface uncovered by the first sealing material 101A and the external connection terminal 452a is connected to the exposed surface via the connection pad 402a. Similarly, the redistribution layer 303b has an exposed surface uncovered by the first sealing material 101A the external connection terminal 452b is connected to the exposed surface via the connection pad 402b.

The external connection terminals 452a and 452b protrude from the side surface of the second sealing material 102A to the outside of the second sealing material 102A, similarly to the external connection terminal 451a, and correspond to terminals IN (LU) and VCCL in FIG. 1, respectively. That is, each of the redistribution layers 303a, 303b, and 301a is a second redistribution layer that electrically connects the first semiconductor chip (e.g., 211L or 201L) among the semiconductor chips to the external connection terminal (e.g., 452a, 452b, or 451a) protruding from the side surface of the second sealing material 102A to the outside. The redistribution layer 303a (the second redistribution layer) has an exposed surface uncovered by the first sealing material 101A and the external connection terminal 452a is connected to the exposed surface. Similarly, the redistribution layer 303b (the second redistribution layer) has an exposed surface uncovered by the first sealing material 101A and the external connection terminal 452b is connected to the exposed surface. The redistribution layer 301a (the second redistribution layer) has an exposed surface uncovered by the first sealing material 101A and the external connection terminal 451a is connected to the exposed surface.

The redistribution layer 304 is provided under (on the −Z side of) the power semiconductor chip 201L. The top surface (the +Z side surface) of the redistribution layer 304 is connected to the drain of the MOSFET of the power semiconductor chip 201L. The bottom surface (the −Z side surface) of the redistribution layer 304 is connected to a conductor pattern formed in the second conductor layer 113 by a bonding layer 421. For example, the redistribution layer 304 and the power semiconductor chip 201L are bonded to each other by a conductive bonding member (not illustrated), such as solder, Ag paste, sintered Ag material, and sintered Cu material. As illustrated in FIG. 2, the redistribution layer 304 is also connected to the external connection terminal 451b via the redistribution layer 301b. The external connection terminal 451b protrudes from the side surface of the second sealing material 102A to the outside and is, for example, the terminal U in FIG. 1. The conductor pattern to which the bonding layer 421 is connected is insulated from another conductor pattern formed in the second conductor layer 113.

As illustrated in FIGS. 4 and 5, the power semiconductor chip 201H and the control semiconductor chip 211H are provided inside the first sealing material 101A. Specifically, both are located in a region away from the region illustrated in FIG. 2 in the −X-direction and arranged in a Y-direction (a direction perpendicular to the thickness direction of the semiconductor apparatus 100A). The power semiconductor chip 201H is a power semiconductor chip including the switch Q₁ in FIG. 1, for example. The control semiconductor chip 211H is a control semiconductor chip corresponding to the HVIC 2U in FIG. 1, for example.

The source and the gate of the MOSFET are formed on the top surface (the +Z side surface) of the power semiconductor chip 201H. The drain of that MOSFET is formed on the bottom surface (the −Z side surface) of the power semiconductor chip 201H. The redistribution layer 311a is provided above the power semiconductor chip 201H and connected to the source of the MOSFET. A connection pad 411a is provided on the redistribution layer 311a. The redistribution layer 311a is connected to the external connection terminal 461a via the connection pad 411a. That is, the redistribution layer 311a has an exposed surface uncovered by the first sealing material 101A and the external connection terminal 461a is connected to the exposed surface via the connection pad 411a. For example, the external connection terminal 461a protrudes from the side surface of the second sealing material 102A to the outside and is the terminal U in FIG. 1.

The redistribution layer 312 is provided above (on the +Z side of) the power semiconductor chip 201H and the control semiconductor chip 211H. The redistribution layer 312 extends in the Y-direction perpendicular to the thickness direction of the semiconductor apparatus 100A. One end of the redistribution layer 312 is bent toward the insulating substrate 110 with respect to the external connection terminal 461a (462b) and connected to the gate of the MOSFET of the power semiconductor chip 201H. The other end of the redistribution layer 312 is also bent toward the insulating substrate 110 with respect to the external connection terminal 461a and connected to a signal terminal of the control semiconductor chip 211H. This signal terminal is, for example, a terminal OUT of the HVIC 2U in FIG. 1. That is, the redistribution layer 312 is the first redistribution layer that electrically connects the first semiconductor chip (e.g., 201H) among the semiconductor chips to the second semiconductor chip (e.g., 211H).

The redistribution layer 315 is provided under (on the −Z side of) the control semiconductor chip 211H. The redistribution layer 316 is provided below the redistribution layer 315. The second conductor layer 113 of the insulating substrate 110 has a conductor pattern formed therein. The redistribution layer 315 is connected to that conductor pattern via a bonding layer (not illustrated). The control semiconductor chip 211H and the redistribution layer 315 are bonded to each other by, for example, a conductive bonding member (not illustrated), such as solder, Ag paste, sintered Ag material, and sintered Cu material. The redistribution layer 315 is a wiring path that supplies a GND potential to the back (the −Z side surface) of the control semiconductor chip 211H. The redistribution layer 316 is connected to another conductor pattern in the second conductor layer 113 via a bonding layer 424. The redistribution layer 316 does not serve as a wiring path but is a redistribution layer for stabilizing adhesion between the first sealing material 101A and the insulating substrate 110, similarly to the redistribution layer 306.

Two signal terminals are provided on the top surface (the +Z side surface) of the control semiconductor chip 211H. One of the signal terminals is, for example, a terminal IN of the HVIC 2U in FIG. 1. The signal terminal is connected to the redistribution layer 313a above (on the +Z side of) the control semiconductor chip 211H and connected to the external connection terminal 462a via a connection pad 412a. The other signal terminal is, for example, a terminal VCC of the HVIC 2U in FIG. 1. The signal terminal is connected to the external connection terminal 462b via the redistribution layer 313b above (on the +Z side of) the control semiconductor chip 211H and the connection pad 412b. That is, the redistribution layer 313a has an exposed surface uncovered by the first sealing material 101A and the external connection terminal 462a is connected to the exposed surface via the connection pad 412a. Similarly, the redistribution layer 313b has an exposed surface uncovered by the first sealing material 101A and the external connection terminal 462b is connected to the exposed surface via the 20) connection pad 412b.

The external connection terminals 462a and 462b protrude from the side surface of the second sealing material 102A to the outside, as with the external connection terminals 451, and correspond to, for example, terminals IN(HU) and VCCH in FIG. 1, respectively. That is, each of the redistribution layers 313a, 313b, and 311a is the second redistribution layer that electrically connects the first semiconductor chip (e.g., 211H or 201H) among the semiconductor chips to the external connection terminal (e.g., 462a, 462b, or 461a) protruding from the side surface of the second sealing material 102A to the outside. The redistribution layer 313a (the second redistribution layer) has an exposed surface uncovered by the first sealing material 101A and the external connection terminal 462a is connected to the exposed surface. Similarly, the redistribution layer 313b (the second redistribution layer) has an exposed surface uncovered by the first sealing material 101A and the external connection terminal 462b is connected to the exposed surface. The redistribution layer 311a (the second redistribution layer) has an exposed surface uncovered by the first sealing material 101A and the external connection terminal 461a is connected to the exposed surface.

The redistribution layer 314 is provided under (on the −Z side of) the power semiconductor chip 201H. The top surface (the +Z side surface) of the redistribution layer 314 is connected to the drain of the MOSFET of the power semiconductor chip 201H. The bottom surface (the −Z side surface) of the redistribution layer 314 is electrically connected to a conductor pattern formed in the second conductor layer 113 by a bonding layer 422. The redistribution layer 314 and the power semiconductor chip 201H are bonded to each other by, for example, a conductive bonding member (not illustrated), such as solder, Ag paste, sintered Ag material, and sintered Cu material. As illustrated in FIG. 4, the redistribution layer 314 is also connected to the external connection terminal 461b via the redistribution layer 311b. The external connection terminal 461b protrudes from the side surface of the second sealing material 102A to the outside and is, for example, the terminal P in FIG. 1. The foregoing description is the configuration of the semiconductor apparatus 100A according to the present embodiment.

According to the present embodiment, the first semiconductor chip is electrically connected to the second semiconductor chip by the first redistribution layer. Furthermore, the first semiconductor chip is electrically connected to an external connection terminal by the second redistribution layer. Therefore, the length of wiring associated with semiconductor chips can be shortened. The wiring inductance can be reduced, and a high-speed 15 switching operation of a power semiconductor chip can be realized.

In addition, for a SiC power semiconductor chip, elements are reduced in size, and the electrode area can be small. A large-current specification does not allow for wire bonding connection for such reasons. The wire bonding connection makes downsizing of the element difficult. According to the present embodiment, a redistribution layer is connected to a power semiconductor chip, in place of bonding wire, and therefore downsizing of the power semiconductor chip is not prevented.

According to the present embodiment, the problem of wire deformation does not occur in a transfer molding structure because a redistribution layer is used as wiring in a sealing material in place of a bonding wire.

Reduction in size of semiconductor apparatuses increases the wiring density, thereby causing a problem of noise generation. However, the present embodiment provides high flexibility of wiring because of a redistribution layer. Such effects avoid increase in the wiring density and reduce noise.

In addition, for a SiC power semiconductor chip of a semiconductor apparatus, a high-speed operation is achieved, and di/dt at the time of the turning off the semiconductor apparatus becomes large. This remains a challenge for suppression of occurrence of overvoltage at the time of turning off. However, according to the present embodiment, overvoltage at the time of turning off can be suppressed because no bonding wire is included in a path of output current i of the power semiconductor chip.

### Second Embodiment

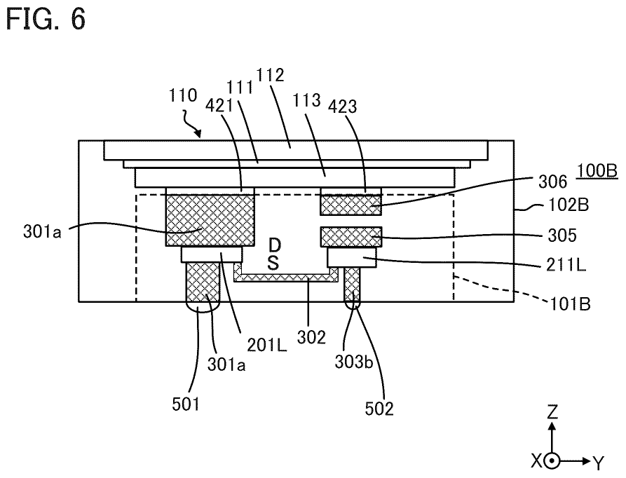

FIG. 6 is a cross-sectional view illustrating a configuration of a semiconductor apparatus 100B according to a second embodiment of this disclosure. FIG. 6 illustrates parts corresponding to the respective parts of the semiconductor apparatus 100A illustrated in FIG. 3 in the first embodiment. The configuration of the semiconductor apparatus 100B illustrated in FIG. 6 is roughly obtained by inverting the semiconductor apparatus 100A in FIG. 3 in the Z-axis direction. A first sealing material 101B includes semiconductor chips and redistribution layers. The insulating substrate 110 is connected to the first sealing material 101B. A second sealing material 102B seals the first sealing material 101B and the insulating substrate 110. While the first sealing material 101B is uncovered by the bottom surface (the −Z side surface) of the second sealing material 102B in the example of FIG. 6, the first sealing material 101B may be covered by the second sealing material 102B.

Differences between the present embodiment and the first embodiment are as follows. In the first embodiment (FIG. 3), the redistribution layers 301a and 303b are respectively connected to the external connection terminals 451a and 452b protruding from the side surface of the second sealing material 102A to the outside. In the present embodiment, the redistribution layer 301a is exposed to the outside of the first sealing material 101B, and a conductor ball 501 serving as an external connection terminal is formed on this exposed surface. Similarly, the redistribution layer 303b is exposed to the outside of the first sealing material 101B, and a conductor ball 502 serving as an external connection terminal is formed on this exposed surface. That is, the redistribution layer 301a (the second redistribution layer) has an exposed surface uncovered by the first sealing material 101B and the conductor ball 501 is connected to the exposed surface. Similarly, the redistribution layer 303b (the second redistribution layer) has an exposed surface uncovered by the first sealing material 101B and the conductor ball 502 is connected to the exposed surface. The redistribution layers 301a and 303b are connected to a circuit board (not illustrated) via the conductor balls 501 and 502, respectively.

Effects identical to those of the first embodiment can be also obtained in the present embodiment. Since a number of conductor balls can be provided throughout one surface of the first sealing material 101B in the present embodiment, an IPM having external connection terminals can be achieved.

### Third Embodiment

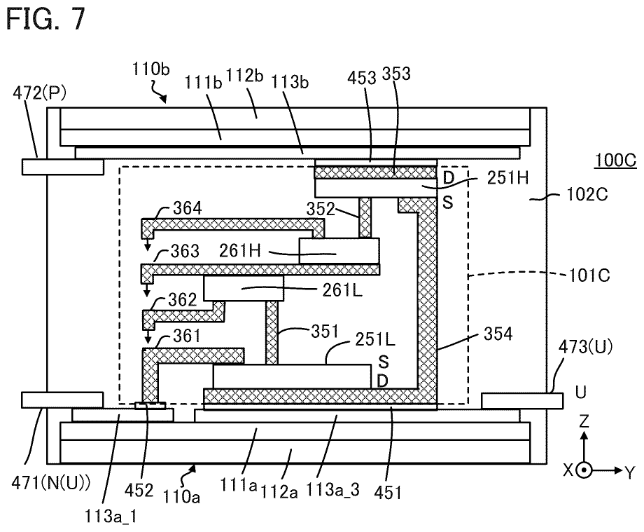

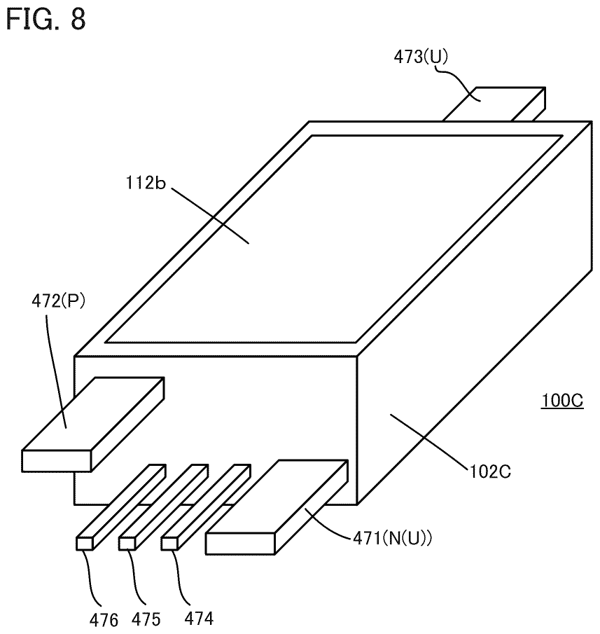

FIG. 7 is a cross-sectional view illustrating a configuration of a semiconductor apparatus 100C according to a third embodiment of this disclosure. FIG. 8 is a perspective view illustrating the appearance of the semiconductor apparatus 100C. FIGS. 7 and 8 illustrate that parts corresponding to one phase (the U-phase in this example) of the IPM 1 illustrated in FIG. 1 are modularized.

The semiconductor apparatus 100C according to the present embodiment includes semiconductor chips, redistribution layers, a first sealing material 101C, a first insulating substrate 110a, a second insulating substrate 110b, and a second sealing material 102C. The semiconductor chips include power semiconductor chips 251L and 251H each including a switch and control semiconductor chips 261L and 261H each including a control circuit for controlling the associated switch. The redistribution layers include a first redistribution layer (a redistribution layer 351, 352, or 354 in the example of FIG. 7) that electrically connects one (the first semiconductor chip) of the semiconductor chips to another one (the second semiconductor chip). The first sealing material 101C seals the semiconductor chips and the redistribution layers. The first insulating substrate 110a includes a first conductor layer 112a, a second conductor layer 113a, and an insulating layer 111a between the first conductor layer 112a and the second conductor layer 113a (113a_1). The second insulating substrate 110b includes a first conductor layer 112b, a second conductor layer 113b, and an insulating layer 111b between the first conductor layer 112b and the second conductor layer 113b. Each of the first and second insulating substrates 110a and 110b is fixed to the first sealing material 101C in such a manner that the semiconductor chips and the redistribution layers are located between the first insulating substrate 110a and the second insulating substrate 110b. The second sealing material 102C seals the first insulating substrate 110a, the first sealing material 101C, and the second insulating substrate 110b.

The semiconductor apparatus 100C further includes external connection terminals 471 to 473 that protrude from the side surface of the second sealing material 102C to the outside. The redistribution layers include third redistribution layers (redistribution layers 353, 354, and 361 to 364 in the example of FIG. 7). Each third redistribution layer is a redistribution layer that electrically connects the first semiconductor chip (251H, 261H, 261L, or 251L in the example of FIG. 7) among the semiconductor chips to the external connection terminal (471, 472, or 473) via the second conductor layer 113a of the first insulating substrate 110a or the second conductor layer 113b of the second insulating substrate 110b.

First, the first sealing material 101C including semiconductor chips and redistribution layers is formed, similarly to the first embodiment. Next, the second conductor layer 113a of the first insulating substrate 110a and the redistribution layers of the first sealing material 101C are bonded to each other to connect the first insulating substrate 110a to the first sealing material 101C. The second conductor layer 113b of the second insulating substrate 110b and the redistribution layer of the first sealing material 101C are bonded to each other to connect the second insulating substrate 110b to the first sealing material 101C. Next, the external connection terminals 471 to 473 are connected to the second conductor layer 113a of the first insulating substrate 110a or the second conductor layer 113b of the second insulating substrate 110b. Subsequently, the first sealing material 101C, the first insulating substrate 110a, the second insulating substrate 110b, and the external connection terminals 471 to 473 are sealed by the second sealing material 102C. In the example of FIG. 7, the first conductor layer 112a of the first insulating substrate 110a and the first conductor layer 112b of the second insulating substrate 110b are uncovered by the second sealing material 102C.

The first sealing material 101C is located between the first insulating substrate 110a and the second insulating substrate 110b. Inside the first sealing material 101C, the power semiconductor chip 251L, the control semiconductor chip 261L, the control semiconductor chip 261H, and the power semiconductor chip 251H are provided to be spaced from each other in the plate thickness direction (the Z-axis direction) of the semiconductor apparatus 100C.

The power semiconductor chip 251L is a power semiconductor chip including the switch Q₂ in FIG. 1, for example. The drain of the MOSFET is formed on the bottom surface (the −Z side surface) of the power semiconductor chip 251L. The source and the gate of the MOSFET are formed on the top surface (the +Z side surface) of the power semiconductor chip 251L. The control semiconductor chip 261L corresponds to the LVIC 3 in FIG. 1, for example. The control semiconductor chip 261L has an element forming surface on which an element and a signal terminal are formed. The element forming surface corresponds to the bottom surface (the −Z side surface) of the control semiconductor chip 261L. The control semiconductor chip 261H corresponds to the HVIC 2U in FIG. 1, for example. The control semiconductor chip 261H has an element forming surface on which an element and a signal terminal are formed. The element forming surface corresponds to the top surface (the +Z side surface) of the control semiconductor chip 261H. The power semiconductor chip 251H is a power semiconductor chip including the switch Q₁ shown in FIG. 1. The drain of the MOSFET is formed on the top surface (the +Z side surface) of the power semiconductor chip 251H. The source and the gate of the MOSFET are formed on the bottom surface (the −Z side surface) of the power semiconductor chip 251H.

The redistribution layer 351 is the first redistribution layer that electrically connects the signal terminal (corresponding to the terminal UOUT of the LVIC 3 in FIG. 1) of the control semiconductor chip 261L to the gate of the MOSFET of the power semiconductor chip 251L. The redistribution layer 352 is the first redistribution layer that electrically connects the signal terminal (corresponding to the terminal OUT of the HVIC 2U in FIG. 1) of the control semiconductor chip 261H to the gate of the MOSFET of the power semiconductor chip 251H.

The bottom surface (the −Z side surface) of the redistribution layer 353 is connected to the drain of the MOSFET of the power semiconductor chip 251H. The top surface (the +Z side surface) of the redistribution layer 353 is connected to a conductor pattern formed in the second conductor layer 113b of the second insulating substrate 110b via a bonding layer 453. This conductor pattern is connected to the external connection terminal 472 that protrudes from the side surface of the second sealing material 102C to the outside. The external connection terminal 472 corresponds to the terminal P in FIG. 1, for example. That is, the redistribution layer 353 is the third redistribution layer that electrically connects the first semiconductor chip (251H) among the semiconductor chips to the external connection terminal 472 via the second conductor layer 113b of the second insulating substrate 110b.

The redistribution layer 354 electrically connects the source of the MOSFET of the power semiconductor chip 251H and the drain of the MOSFET of the power semiconductor chip 251L to each other. In this case, the redistribution layer 354 is the first redistribution layer that electrically connects the first semiconductor chip (e.g., 251L) to the second semiconductor chip (e.g., 251H). The power semiconductor chip 251H and the redistribution layer 354 are bonded to each other by, for example, a conductive bonding member (not illustrated), such as solder, Ag paste, sintered Ag material, and sintered Cu material.

The bottom surface (the −Z side surface) of the redistribution layer 354 is connected to a conductor pattern 113a_3 formed in the second conductor layer 113a of the first insulating substrate 110a via a bonding layer 451. The conductor pattern 113a_3 is connected to the external connection terminal 473 corresponding to the terminal U in FIG. 1. In this case, the redistribution layer 354 is the first redistribution layer and is also the third redistribution layer.

One end of the redistribution layer 361 is connected to the source of the MOSFET of the power semiconductor chip 251L. The other end of the redistribution layer 361 is connected to a conductor pattern 113a_1 formed in the second conductor layer 113a of the first insulating substrate 110a via a bonding layer 452. The conductor pattern 113a_1 is connected to the external connection terminal 471 corresponding to the terminal N(U) in FIG. 1. The redistribution layer 361 is the third redistribution layer that electrically connects the first semiconductor chip (251L) among the semiconductor chips to the external connection terminal 471 via the second conductor layer 113a of the first insulating substrate 110a.

One end of the redistribution layer 362 is connected to the signal terminal (corresponding to the terminal UIN of the LVIC 3 in FIG. 1) of the control semiconductor chip 261L. This signal terminal is located on the bottom surface (the −Z side surface) of the control semiconductor chip 261L. A portion of the redistribution layer 363 is connected to the top surface (the +Z side surface) of the control semiconductor chip 261L and the bottom surface (the −Z side surface) of the control semiconductor chip 261H. The control semiconductor chip 261H and the redistribution layer 363 are bonded to each other by, for example, a conductive bonding member (not illustrated), such as solder, Ag paste, sintered Ag material, and sintered Cu material. One end of the redistribution layer 364 is connected to the signal terminal (corresponding to the terminal IN of the HVIC 2U in FIG. 1) of the control semiconductor chip 261H. This signal terminal is located on the top surface (the +Z side surface) of the control semiconductor chip 261H.

The other end of each of the redistribution layers 362, 363, and 364 is connected to a corresponding conductor pattern (not illustrated) formed in the second conductor layer 113a of the first insulating substrate 110a via a corresponding bonding layer (not illustrated). Each conductor pattern is connected to a corresponding external connection terminal (not illustrated). As illustrated in FIG. 8, an external connection terminal 474 to which the redistribution layer 362 is connected corresponds to the terminal IN (LU) in FIG. 1. For example, an external connection terminal 475 to which the redistribution layer 363 is connected corresponds to a terminal COM in FIG. 1. That is, the redistribution layer 363 supplies a GND potential to a semiconductor substrate of each of the control semiconductor chips 261L and 261H. For example, an external connection terminal 476 to which the redistribution layer 364 is connected corresponds to the terminal IN(HU) in FIG. 1. Thus, each of the redistribution layers 362 to 364 is the third redistribution layer that electrically connects the first semiconductor chip among the semiconductor chips to the external connection terminal via the second conductor layer 113a of the first insulating substrate 110a or the second conductor layer 113b of the second insulating substrate 110b.

Effects identical to those of the first embodiment can also be obtained in the present embodiment. Since a high-side element and a low-side element are stacked in the vertical direction in the present embodiment, the occupied area of a semiconductor apparatus in a plane can be reduced, so that the entire apparatus can be reduced in size. Furthermore, since an insulating substrate is provided on each side in the plate thickness direction of a semiconductor apparatus in the present embodiment, the heat dissipation effect is high even when the high-side element and the low-side element are stacked in the vertical direction.

### Modification

The first to third embodiments of this disclosure have been explained, but modifications can be conceived in this disclosure. Examples of such modifications follow.

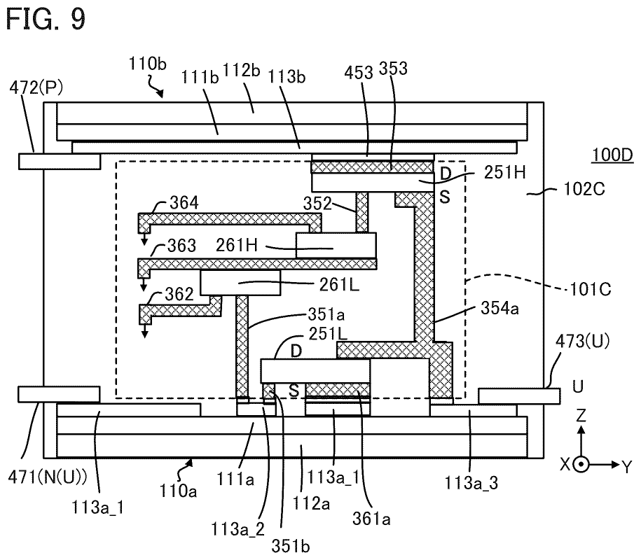

FIG. 9 is a cross-sectional view illustrating a configuration of a semiconductor apparatus 100D that is a modification of the third embodiment (see FIG. 7). In FIG. 9, parts corresponding to those of FIG. 7 are denoted by reference signs common to FIG. 7 and explanations thereof are omitted.

In this modification, the orientation of the power semiconductor chip 251L is opposite to the orientation of the power semiconductor chip 251L in the third embodiment. That is, the drain of the MOSFET is formed on the top surface (the +Z side surface) of the power semiconductor chip 251L. The gate and the source of that MOSFET are formed on the bottom surface (the −Z side surface) of the power semiconductor chip 251L.

Redistribution layers associated with the power semiconductor chip 251L are also changed with this change in the orientation of the power semiconductor chip 251L.

The gate of the MOSFET is located in the bottom surface (the −Z side surface) of the power semiconductor chip 251L. A redistribution layer 351b connects the gate of the MOSFET of the power semiconductor chip 251L to a conductor pattern 113a_2 formed in the second conductor layer 113a of the first insulating substrate 110a. A signal terminal (corresponding to the terminal UOUT of the LVIC 3 in FIG. 1) is provided on the bottom surface (the −Z side surface) of the control semiconductor chip 261L. A redistribution layer 351a connects the conductor pattern 113a_2 to the signal terminal (corresponding to the terminal UOUT of the LVIC 3 in FIG. 1).

The source of the MOSFET is provided on the bottom surface (the −Z side surface) of the power semiconductor chip 251L. A redistribution layer 361a connects the source of the MOSFET of the power semiconductor chip 251L to the conductor pattern 113a_1 formed in the second conductor layer 113a of the first insulating substrate 110a. The external connection terminal 471 corresponding to the terminal N(U) in FIG. 1 is connected to the conductor pattern 113a_1.

The source of the MOSFET is provided on the bottom surface (the −Z side surface) of the power semiconductor chip 251H. The drain of the MOSFET is provided on the top surface (the +Z side surface) of the power semiconductor chip 251L. A redistribution layer 354a electrically connects the source of the MOSFT of the power semiconductor chip 251H to the drain of the MOSFT of the power semiconductor chip 251L. The redistribution layer 354a is also connected to the conductor pattern 113a_3 formed in the second conductor layer 113a of the first insulating substrate 110a. The conductor pattern 113a_3 is connected to the external connection terminal 473 corresponding to the terminal U in FIG. 1. Effects identical to those of the third embodiment can be also obtained in this mode.

In the foregoing embodiments, a power semiconductor chip is configured by a MOSFET, the power semiconductor chip may be configured by an IGBT (Insulated Gate Bipolar Transistor) and another type of element, such as a diode, connected to the IGBT in anti-parallel connection. The power semiconductor chip is configured by a SiC wide band-gap semiconductor element, but an Si element may be used.

In the foregoing embodiments, this disclosure is applied to an IPM including a power semiconductor chip and a control semiconductor chip. This disclosure may be applied to a semiconductor apparatus including a power semiconductor chip only. That is, the semiconductor apparatus according to this disclosure may be a power semiconductor module, in which the HVICs and the LVIC are omitted from the configuration of FIG. 1 and only the switches Q₁ to Q₆ are connected to each other by redistribution layers.

In the foregoing embodiments, a semiconductor apparatus for one element or one phase has been described. However, the semiconductor apparatus according to this disclosure may be a so-called 6-in-1 package in which components for three phases are accommodated in one package.

### DESCRIPTION OF REFERENCE SIGNS

1 . . . IPM, Q₁ to Q₆ . . . switch, 2U,2V,2W . . . HVIC, 3 . . . LVIC, 100A,100B,100C,100D . . . semiconductor apparatus, 101A,101B,101C . . . first sealing material, 102A,102B,102C . . . second sealing material, 110 . . . insulating substrate, 110a . . . first insulating substrate, 110b . . . second insulating substrate, 111,111a,111b . . . insulating layer, 112,112a, 112b . . . first conductor layer, 113,113a, 113b . . . second conductor layer, 113a_1, 113a_2, 113a_3 . . . conductor pattern, 201L,231L,201H,231H,251L,251H . . . power semiconductor chip, 211L,211H,241L,261L,261H . . . control semiconductor chip, 301a,301b,302,303a,303b,304,305,306,311a,311b,312,313a,313b,314,315,3 16,351 to 354,361 to 364 . . . redistribution layer, 401a,401b . . . connection pad, 451 to 453,456,457 . . . bonding layer, 501,502 . . . conductor ball.

What is claimed is:

1. A semiconductor apparatus comprising:
a plurality of semiconductor chips including:
a power semiconductor chip including a switch; and
a control semiconductor chip including a control circuit configured to control the switch;
a plurality of redistribution layers including a first redistribution layer that electrically connects a first semiconductor chip to a second semiconductor chip from among the plurality of semiconductor chips;
a first sealing material that seals the plurality of semiconductor chips and the plurality of redistribution layers;
an insulating substrate including:
a first conductor layer;
a second conductor layer; and
an insulating layer between the first and second conductor layers, wherein the insulating substrate is fixed to the first sealing material to be opposed to the plurality of semiconductor chips and the plurality of redistribution layers; and
a second sealing material that seals the insulating substrate and the first sealing material.

2. The semiconductor apparatus according to claim 1, wherein the plurality of redistribution layers include a second redistribution layer that electrically connects the first semiconductor chip to an external connection terminal protruding to an outside of the second sealing material.

3. The semiconductor apparatus according to claim 2, wherein the external connection terminal protrudes from a side surface of the second sealing material to an outside thereof.

4. The semiconductor apparatus according to claim 2, wherein:
the second distribution layer has an exposed surface uncovered by the first sealing material, and
the external connection terminal is connected to the exposed surface.

5. A semiconductor apparatus comprising:
a plurality of semiconductor chips including:
a power semiconductor chip including a switch; and
a control semiconductor chip including a control circuit configured to control the switch;
a plurality of redistribution layers including a first redistribution layer that electrically connects a first semiconductor chip to a second semiconductor chip from among the plurality of semiconductor chips;
a first sealing material that seals the plurality of semiconductor chips and the plurality of redistribution layers;
a first insulating substrate;
a second insulating substrate; and
a second sealing material,
wherein each of the first and second insulating substrates includes:
a first conductor layer;
a second conductor layer; and
an insulating layer between the first and second conductor layers,
wherein each of the first and second insulating substrates is fixed to the first sealing material such that the plurality of semiconductor chips and the plurality of redistribution layers are located between the first and second insulating substrates, and
wherein the second sealing material seals the first insulating substrate, the first sealing material, and the second insulating substrate.

6. The semiconductor apparatus according to claim 5, further comprising an external connection terminal protruding from a side surface of the second sealing material surrounding a region between the first and second insulating substrates to an outside of the second sealing material,
wherein the plurality of redistribution layers include a third redistribution layer that electrically connects the first semiconductor chip from among the plurality of semiconductor chips to the external connection terminal via the second conductor layer of the first insulating substrate or the second insulating substrate.
